(19) United States
(12) Patent Application Publication
(10) Pub. No.: US 2026/0206236 A1
(43) Pub. Date: Jul. 16, 2026

(54) VARIABLE RESISTANCE MEMORY DEVICE

(71) Applicant: SK hynix Inc., Gyeonggi-do (KR)

(72) Inventor: Kyung Wan KIM, Gyeonggi-do (KR)

(21) Appl. No.: 19/243,694

(22) Filed: Jun. 20, 2025

(30) Foreign Application Priority Data
Jan. 15, 2025 (KR) 10-2025-0005974

(51) Int. Cl. H10B 63/00

(52) U.S. Cl. CPC H10B 63/30

(57) ABSTRACT

A variable resistance memory device may include a control circuit block, a first deck and a second deck. The first deck may include first word lines and first bit lines spaced apart from the control circuit block by a first distance and intersected with each other, and first memory cells located at intersections between the first word lines and the first bit lines. The second deck may include the first bit lines and second word lines spaced apart from the control circuit block by a second distance greater than the first distance and intersected with each other, and second memory cells positioned at intersections between the first bit lines and the second word lines. The relative ratios of thickness of the first bit lines, the first word lines, and the second word lines are configured to reduce an effect of spike currents.

### CROSS-REFERENCE TO RELATED APPLICATION

The present application claims priority under 35 U.S.C. § 119(a) to Korean application number 10-2025-0005974, filed on Jan. 15, 2025, in the Korean Intellectual Property Office, which is incorporated herein by reference in its entirety.

### BACKGROUND

### 1. Technical Field

Example embodiments relate to an electronic device, and more specifically, to a variable resistance memory device using a variable resistor as a storage medium.

### 2. Related Art

Currently, there is a lot of research being done to develop next-generation memory devices to replace DRAM (dynamic random access memory) and flash memory. One of these next-generation memory devices is a variable resistance memory device. The variable resistance memory device may utilize a variable resistance layer (or variable resistor) as a memory layer. Depending on the types of the variable resistance layer, the variable resistance memory device may be classified as PCRAM (phase-change random access memory), ReRAM (resistive random access memory), MRAM (magnetic random access memory), or FeRAM (ferroelectric random access memory).

The variable resistance memory device may be configured as a cross-point array structure. The cross-point array type variable resistance memory device may include multiple memory cells. The memory cells of the cross-point array type variable resistance memory device may have different operation characteristics or error generation rates depending on a distance from a control circuit block.

### SUMMARY

Example embodiments provide a variable resistance memory device that may be capable of reducing differences in operational characteristics of memory cells based on positions of the memory cells.

According to example embodiments, there may be provided a variable resistance memory device. The variable resistance memory device may include a control circuit block, a first deck and a second deck. The control circuit block may output a plurality of control voltages.

In example embodiments, the first deck may be spaced apart from the control circuit block by a first distance. The first deck may include a plurality of first word lines, a plurality of first bit lines intersected with the plurality of first word lines, and a plurality of first memory cells each positioned at intersections between the plurality of first word lines and the plurality of first bit lines.

In example embodiments, the second deck may be spaced apart from the control circuit block by a second distance greater than the first distance. The second deck may include the plurality of first bit lines, a plurality of second word lines intersected with the plurality of first bit lines, and a plurality of second memory cells positioned at intersections between the plurality of first bit lines and the plurality of second word lines.

In example embodiments, relative ratios of thickness of the first bit lines, the first word lines, and the second word lines are configured, based on the first distance and the second distance, to reduce an effect of sudden spike currents.

In example embodiments, a ratio of a thickness of the plurality of first bit lines to a thickness of the plurality of first word lines may have a first ratio. A ratio of the thickness of the plurality of first bit lines to a thickness of the plurality of second word lines may have a second ratio less than the first ratio.

According to example embodiments, there may be provided a variable resistance memory device. The variable resistance memory device may include a control circuit block, a first deck, a second deck, a third deck and a fourth deck.

In example embodiments, the first deck may include a plurality of first memory cells stacked over the control circuit block. The plurality of first memory cells may be connected between a plurality of first word lines and the plurality of first bit lines. Each of the plurality of first memory cells may have a first width.

In example embodiments, the second deck may include a plurality of second memory cells stacked on the first deck. The plurality of second memory cells may be connected between the plurality of first bit lines and a plurality of second word lines. Each of the plurality of second memory cells may have a second width greater than the first width.

In example embodiments, the third deck may include a plurality of third memory cells stacked on the second deck. The third deck may be connected between the plurality of second word lines and a plurality of second bit lines. Each of the plurality of third memory cells may have a third width greater than the second width.

In example embodiments, the fourth deck may include a plurality of fourth memory cells stacked on the third deck. The plurality of fourth memory cells may be connected between the plurality of second bit lines and a plurality of third word lines. Each of the fourth memory cells may have a fourth width wider than the third width.

According to example embodiments, a variable resistance memory device may be provided. The variable resistance memory device may include a control circuit block, a plurality of word lines and a plurality of bit lines and a plurality of variable resistors. The plurality of word lines and the plurality of bit lines may be alternately intersected and stacked on the control circuit block. The plurality of variable resistors may be connected to each of intersections between the plurality of word lines and the plurality of bit lines. A capacitance of each of the plurality of word lines and the plurality of bit lines is adjusted based on proximity to the control circuit block to reduce an effect of spike currents. At least one of a thickness and a width of the plurality of word lines may be decreased in proximity to the control circuit block. At least one of a thickness and a width of the plurality of bit lines may be decreased in proximity to the control circuit block. A thickness of the word line connected with one end of the variable resistor may be thinner than a thickness of the bit line connected with the other end of the variable resistor.

According to example embodiments, in a stacked memory device, a ratio of the bit line thickness to the word line thickness ratio, and the width of the memory cell may be adjusted in accordance with a distance from the control circuit block to prevent malfunctions caused by sudden spike currents during a memory cell selection.

### BRIEF DESCRIPTION OF THE DRAWINGS

The above and other aspects, features and advantages of the subject matter of the present disclosure will be more easily understood from the following detailed description taken in conjunction with the accompanying drawings, in which:

FIG. 1 is a block diagram illustrating an electronic system in accordance with example embodiments;

FIG. 2 is a cross-sectional view illustrating a variable resistance memory device in accordance with example embodiments;

FIG. 3 is a block diagram illustrating a memory deck in accordance with example embodiments;

FIG. 4 is an equivalent circuit diagram illustrating a memory cell in accordance with example embodiments;

FIG. 5 is a graph showing changes of drive voltages over time to illustrate a driving of a memory cell in accordance with example embodiments;

FIGS. 6A and 6B are cross-sectional views illustrating a memory cell array including a plurality of stacked decks in accordance with example embodiments;

FIG. 7 is a graph showing changes of word line capacitance as a function of bit line thickness ratio (BL/WL) to word line thickness of a variable resistance memory device in accordance with example embodiments;

FIG. 8 is a graph showing a ratio of bit line thickness to word line thickness per a deck in accordance with example embodiments; and

FIGS. 9A and 9B are cross-sectional views illustrating a memory cell array including a plurality of stacked memory decks in accordance with example embodiments.

### DETAILED DESCRIPTION

The advantages and features of the present disclosure, and methods of achieving them, will become apparent upon reference to the embodiments described in detail with reference to the accompanying drawings. The embodiments of the present disclosure are not limited to the implementations mentioned in this specification, and other implementations not mentioned will be clearly understood by those skilled in the art from the description below. The dimensions and relative sizes of the layers and regions in the drawings may be exaggerated for clarity of description. Throughout the specification, like reference numerals refer to like components.

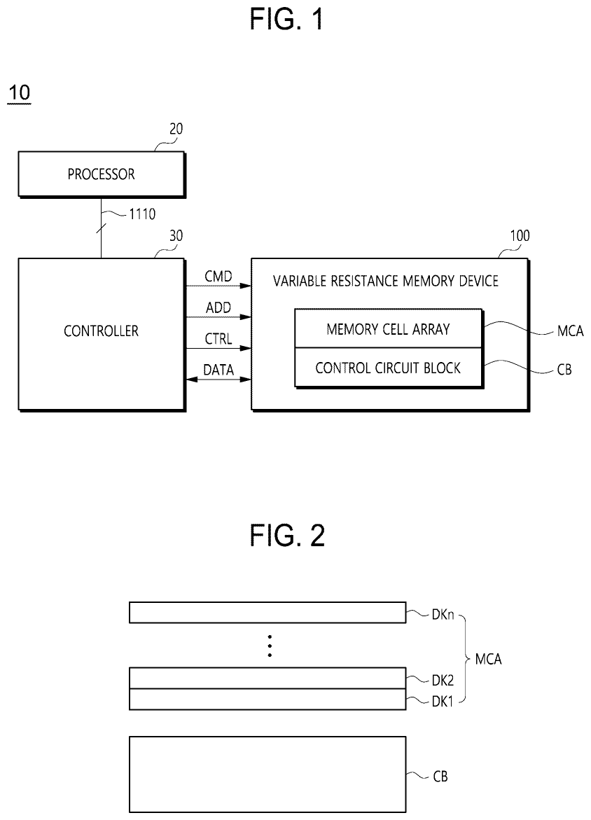

FIG. 1 is a block diagram illustrating an electronic system 10 in accordance with example embodiments.

Referring to FIG. 1, the electronic system 10 may include a processor 20, a controller 30 and a variable resistance memory device 100.

The processor 20 may be interfaced with the controller 30 by a plurality of buses 1110. The processor 20 may transmit a memory access request (e.g., a read or write request), which may include a memory address and data, to the controller 30.

The controller 30 may generate commands CMD such as read commands and write commands, addresses ADDs, data DATA and control commands CTRL for memory operations of the variable resistance memory device 100. The controller 30 may then provide the commands CMD to the variable resistance memory device 100. At least one of the commands CMD, addresses ADD, data DATA and control commands CTRL may be generated based on the memory access request.

The variable resistance memory device 100 may be, for example, a variable resistance memory device. The variable resistance memory device 100 may include a memory cell array MCA and a control circuit block CB.

The memory cell array MCA may include a plurality of memory cells arranged in a cross-point array.

The control circuit block CB may control memory operations of the plurality of memory cells of the memory cell array MCA based on the command CMD, address ADD, data DATA and control command CTRL provided from the controller 30.

Example embodiments disclosed herein may provide a variable resistance memory device 100 capable of reducing differences in operational characteristics of memory cells based on positions of the memory cells.

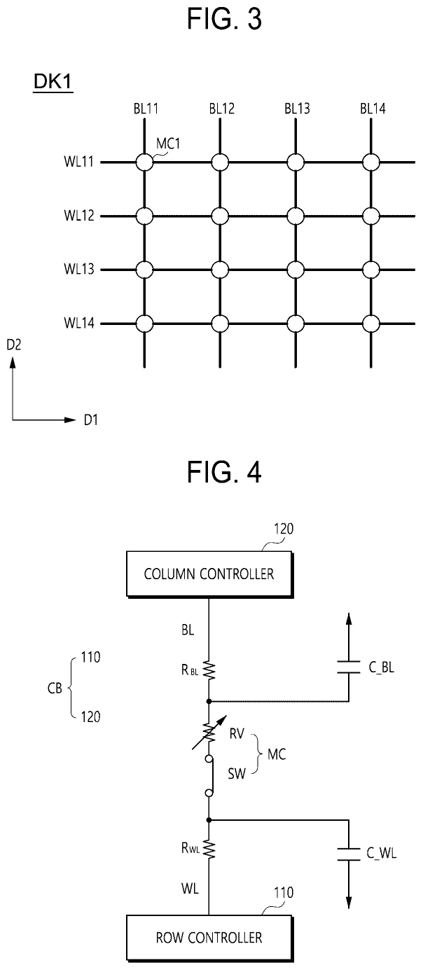

FIG. 2 is a cross-sectional view illustrating a variable resistance memory device in accordance with example embodiments. FIG. 3 is a block diagram illustrating a memory deck in accordance with example embodiments.

Referring to FIGS. 2 and 3, the memory cell array MCA and the control circuit block CB of the variable resistance memory device 100 may be stacked.

In example embodiments, the control circuit block CB may be located below the memory cell array MCA. The control circuit block CB and the memory cell array MCA may be located on different wafers. The control block CB and the memory cell array MCA may then be electrically connected with each other by a wafer bonding. Alternatively, the control circuit block CB and the memory cell array MCA may be stacked sequentially on the same wafer.

The memory cell array MCA may include a plurality of stacked memory decks DK1-DKn. A memory deck (or deck) in this instance refers to a specific layer or group of memory cells within a larger memory array. The memory deck may perform as a separate portion of storage in which data can be accessed independently. In example embodiments, a first deck DK1 of the plurality of memory decks DK1-DKn may include a plurality of first word lines WL11-WL14, a plurality of first bit lines BL11-BL14, and a plurality of first memory cells MC1, as shown in FIG. 3.

For example, the plurality of first word lines WL11-WL14 may extend in parallel, along a first direction D1. The plurality of first bit lines BL11-BL14 may extend in parallel along a second direction D2 intersected with the plurality of first word lines WL11-WL14. In example embodiments, the plurality of first bit lines BL11-BL14 may be disposed over the plurality of word lines WL11-WL14 (e.g., toward a third direction D3).

The plurality of first memory cells MC1 may be located at intersections between the plurality of first word lines WL11-WL14 and the plurality of first bit lines BL11-BL14, respectively. The plurality of first memory cells MC1 may each include a variable resistor as a storage medium. Alternatively, each of the plurality of first memory cells MC may include a variable resistor and a switching element connected in series. For example, the variable resistor may include a magnetic material, a transition metal compound, a ferroelectric, or a phase change material layer. Accordingly, the plurality of first memory cells MC1 may be resistive memory cells.

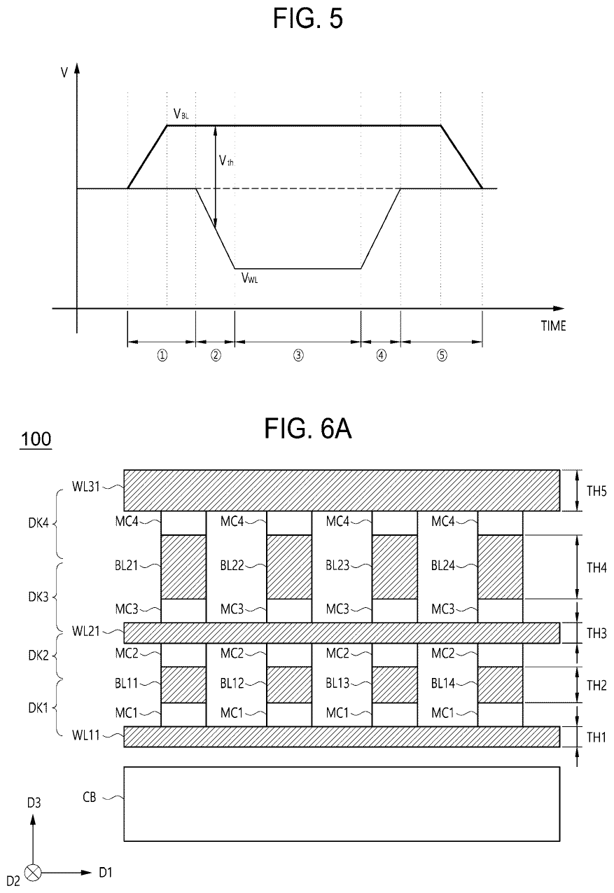

FIG. 4 is an equivalent circuit diagram illustrating a memory cell in accordance with example embodiments, and FIG. 5 is a graph showing variations of drive voltages over time to illustrate operations of a memory cell in accordance with example embodiments.

Referring to FIGS. 4 and 5, the memory cell MC may be connected between a word line WL and a bit line BL.

The word line WL may be electrically coupled to the row controller 110 to selectively receive a word line voltage V_{WL}. In example embodiments, the row controller 110 may include a word line decoder of a variable resistance memory device such as a variable resistance memory device. The row controller 110 may be integrated into a control circuit block CB.

The bit line BL may be electrically coupled to a column controller 120 to selectively receive a bit line voltage V_{BL}. The bit line voltage V_{BL} may include, for example, a write voltage or a read voltage. In example embodiments, the column controller 120 may include a bit line decoder of a variable resistance memory device such as a variable resistance memory device. The column controller 120 may be integrated into the control circuit block CB, as is the row controller 110.

The memory cell MC may include a switching element SW and a variable resistor Rv. The variable resistor Rv may include a material whose resistance value may be changed in accordance with a difference between the bit line voltage V_{BL} and the word line voltage V_{WL} transmitted through the switching element SW. For example, when the difference between the bit line voltage V_{BL} and the word line voltage V_{WL} transmitted through the switching element SW is greater than (or equal to) a threshold voltage Vₜₕ, the variable resistor Rv may be changed to a low resistance state. The variable resistor Rv may include, for example, a magnetic material, a transition metal compound, a ferroelectric, or a phase change material.

Further, in FIG. 4, a reference character R_{WL} may indicate a word line resistance. The word line resistance R_{WL} may be determined by a distance between the memory cell MC and the row controller 110, a physical property of the word line WL, and a width of the word line WL. A reference character R_{BL} may indicate a bit line resistance. The bit line resistance R_{BL} may be determined by a distance between the memory cell MC and the column controller 120, a physical property of the bit line BL, and a width of the bit line BL, and the like.

In response to receiving an address ADD by the variable resistance memory device 100 from the memory controller 30 (see FIG. 1), the control circuit block CB may select any one of the plurality of memory cells.

The column controller 120 of the control circuit block CB may apply a bit line voltage V_{BL} to the bit line BL (hereinafter, a selected bit line) connected with a selected memory cell MC (\textcircled{1}).

When a voltage level of the selected bit line BL may reach a voltage level of the bit line voltage V_{BL}, the row controller 110 of the control circuit block CB may apply the word line voltage V_{WL} to the word line WL (hereinafter, the selected word line) connected with the selected memory cell MC (\textcircled{2}).

In example embodiments, in instances in which the bit line BL and the word line WL are selected, the switching element SW may be turned on before the variable resistor Rv. Accordingly, the bit line voltage V_{BL} may be applied to a first terminal of the variable resistor Rv and the word line voltage V_{WL} may be applied to a second terminal of the variable resistor Rv.

In instances in which a voltage difference between the first and second terminals of the variable resistor Rv is greater than or equal to (or exceeds) the threshold voltage Vₜₕ, the variable resistor Rv may be changed to a low resistance level. Accordingly, a write operation may be performed on the memory cell MC (\textcircled{3}).

After the write operation of the variable resistor Rv is completed, the row controller 110 may cut off a supply of word line voltage V_{WL} to the selected word line WL (\textcircled{4}).

Subsequently, the column controller 120 may also cut off a supply of bit line voltage V_{BL} supplied to the selected bit line BL (\textcircled{5}).

However, in an interval where the difference between the word line voltage V_{WL} and the bit line voltage V_{BL} may become the threshold voltage Vₜₕ, i.e., in the turn-on interval (\textcircled{2}) of the memory cell MC and/or the deselection interval (\textcircled{4}) of the memory cell MC, an unexpected transient current (hereinafter, a spike current) may be applied to the memory cell MC.

The spike current may be generated due to a parasitic capacitance of the selected word line WL and/or a parasitic capacitance of the selected bit line BL. The spike current may cause a malfunction of the memory cell, since a sudden excessive amount of current may be applied to the memory cell. Referring to FIG. 5, since the spike current may be generated instantaneously at the time of turn-on of the memory cell, it may be dominantly influenced by changes in the word line voltage V_{WL}, which may determine the turn-on of the memory cell.

Further, a magnitude of the spike current may be variable depending on an amount of charge of the word line capacitor C_WL connected to the selected memory cell (hereinafter, the word line capacitance) and the resistance R_{WL} of the word line.

The word line capacitance and the word line resistance R_{WL} may depend on a thickness of the word lines, a gap between adjacent word lines and properties of the word lines, etc. For example, the word line capacitance and the word line resistance R_{WL} of the first word lines may depend on the gap between adjacent members of the first word lines.

Furthermore, in the case of a cross-point array type variable resistance memory device of example embodiments, the word line capacitance may be variable due to factors such as a frequency of selection of the word line and a disturbance caused by a selection of the adjacent word lines. Accordingly, the magnitude of the spike current may be proportional to the word line capacitance and inversely proportional to the word line resistance R_{WL}.

In the opposite case to FIG. 5, where a positive word line voltage may be applied to the word line WL and a negative bit line voltage may be applied to the bit line BL, the turn-on time of the memory cell may be dependent on the change in the bit line voltage V_{BL}. In this case, the spike current may be affected by the bit line capacitance and the bit line resistance.

However, as shown in FIG. 2., the plurality of decks may be stacked sequentially. The memory cells (in these instances referred to as near memory cells) disposed relatively close to the control circuit block CB may have a relatively small word line resistance R_{WL}, which is a component capable of controlling the spike current. The generation frequency of the spike current in the near memory cells may be relatively high.

Even in instances in which the memory cell is not a near memory cell (i.e., the memory cell, for example, a far memory cell, is not close to the control circuit block CB), the word line capacitance may be a parasitic component so that the word line capacitance may generate leakage currents causing the malfunction of the memory cell.

Accordingly, the following example embodiments may describe techniques for mitigating the spike current in near memory cells and avoiding signal delays in far memory cells, thereby reducing characteristic deviations due to a separation distance between the control circuit block and the memory cells. Further, in example embodiments, the near memory cells and far memory cells may be arbitrarily set, such as by considering bit error rates per deck of a variable resistance memory device.

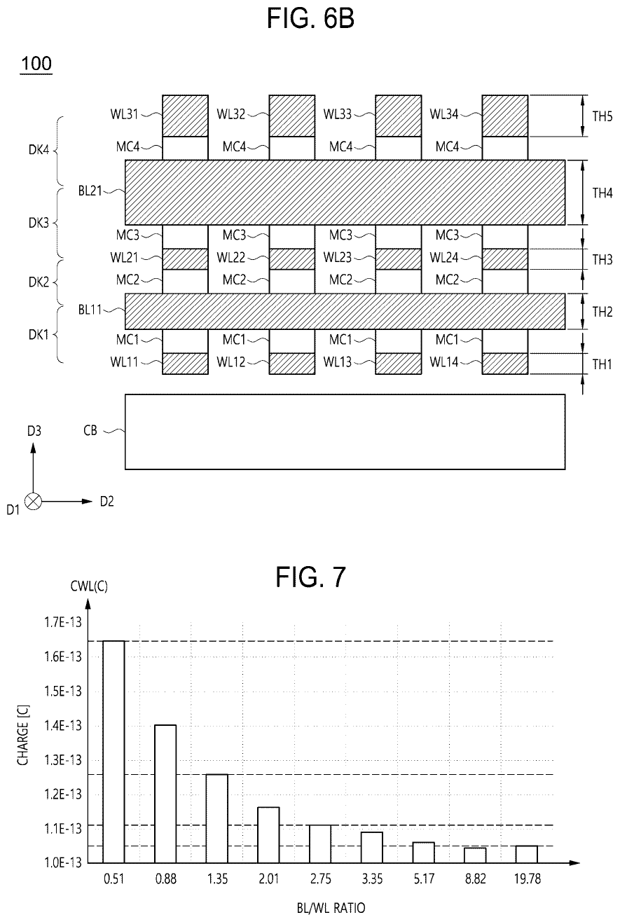

FIGS. 6A and 6B are cross-sectional views illustrating a memory cell array including a plurality of stacked decks in accordance with example embodiments. For example, FIG. 6A is a cross-sectional view taken along in a direction parallel to a first 1-1 word line, and FIG. 6B is a cross-sectional view taken along in a direction parallel to a first 1-1 bit line.

Referring to FIGS. 6A and 6B, the memory cell array MCA may include first to fourth decks DK1-DK4 sequentially stacked. For example, a first deck DK1 may be spaced apart from a control circuit block CB by a first distance. A second deck DK2 may be spaced apart from the control circuit block CB by a second distance greater than the first distance. A third deck DK3 may be spaced apart from the control circuit block CB by a third distance greater than the second distance. A fourth deck DK4 may be spaced apart from the control circuit block CB by a fourth distance greater than the third distance. In example embodiments, the first to fourth distances may be parallel to the third direction D3 of the drawing.

The first deck DK1 may include a plurality of first word lines, a plurality of first bit lines and a plurality of first memory cells.

The plurality of first word lines, e.g., the 1-1 to 1-4 word lines WL11-WL14, may extend parallel to each other along the first direction D1. The 1-1 to 1-4 word lines WL11-WL14 may be formed to have a first thickness TH1.

The plurality of first bit lines, e.g., the 1-1 to 1-4 bit lines BL11-BL14, may be positioned over the 1-1 to 1-4 word lines WL11-WL14 (e.g., toward the third direction D3). The 1-1 to 1-4 bit lines BL11-BL14 may extend parallel to each other along a second direction D2 intersected with the 1-1 to 1-4 word lines WL11-WL14. The 1-1 to 1-4 bit lines BL11-BL14 may be formed to have a second thickness TH2 different from the first thickness TH1.

The plurality of first memory cells MC1 may be positioned at the intersections between the 1-1 to 1-4 word lines WL11-WL14 and the 1-1 to 1-4 bit lines BL11-BL14, respectively. For example, the first deck DK1 may include 16 first memory cells MC1. A first insulation layer may be further interposed between the 1-1 to 1-4 word lines WL11-WL14 and the 1-1 to 1-4 bit lines BL11-BL14. The first memory cells MC1 may be isolated from each other by the first insulation layer.

The second deck DK2 may be arranged over the first deck DK1. The second deck DK1 may include the 1-1 to 1-4 bit lines BL11-BL14, a plurality of second word lines and a plurality of second memory cells MC2. For example, the second deck DK2 and the first deck DK1 may share the 1-1 to 1-4 bit lines BL11-BL14.

For example, the plurality of second word lines may include 2-1 to 2-4 word lines WL21-WL24. The 2-1 to 2-4 word lines WL21-WL24 may be arranged parallel along the first direction D1, on the 1-1 to 1-4 bit lines BL11-BL14. Each of the 2-1 to 2-4 word lines WL21-WL24 may be formed to have a third thickness TH3 different from the first and second thicknesses TH1 and TH2.

Each of the plurality of second memory cells MC2 may be located at intersections between the 1-1 to 1-4 bit lines BL11-BL14 and the 2-1 to 2-4 word lines WL21-WL24. The second deck DK2 may also include 16 second memory cells MC2.

Further, a second insulation layer may be interposed between the 1-1 to 1-4 bit lines BL11-BL14 and the 2-1 to 2-4 word lines WL21-WL24. For example, the second memory cells MC2 may be isolated by the second insulation layer.

The third deck DK3 may be arranged over the second deck DK2. The third deck DK3 may include the 2-1 to 2-4 word lines WL21-WL24, a plurality of second bit lines and a plurality of third memory cells MC3. That is, the third deck DK3 and the second deck DK2 may share the 2-1 to 2-4 word lines WL21-WL24.

The plurality of second bit lines may include 2-1 to 2-4 bit lines BL21-BL24. The 2-1 to 2-4 bit lines BL21-BL24 may be disposed over the 2-1 to 2-4 word lines WL21-WL24 to be intersected with the 2-1 to 2-4 word lines WL21-WL24. The 2-1 to 2-4 bit lines BL21-BL24 may overlap with the 1-1 to 1-4 bit lines BL11-BL14, respectively. Each of the 2-1 to 2-4 bit lines BL21-BL24 may be formed to have a fourth thickness TH4 different from the first to third thicknesses TH1-TH3.

The plurality of third memory cells MC3 may be located at intersections between the 2-1 to 2-4 word lines WL21-WL24 and the 2-1 to 2-4 bit lines BL21-BL24, respectively. Accordingly, the third deck DK3 may include 16 third memory cells MC3.

A third insulation layer may be interposed between the plurality of third memory cells MC3. In addition to insulating between the third memory cells MC3, the third insulation layer may insulate between 2-1 to 2-4 word lines WL21-WL24 and the 2-1 to 2-4 bit lines BL21-BL24, respectively.

The fourth deck DK4 may include the 2-1 to 2-4 bit lines BL21-BL24, a plurality of third word lines and a plurality of fourth memory cells MC4. The fourth deck DK4 and the third deck DK3 may share the 2-1 to 2-4 bit lines BL21-BL24.

The plurality of third word lines may include, for example, 3-1 to 3-4 word lines WL31-WL34. The 3-1 to 3-4 word lines WL31-WL34 may extend parallel to each other to be intersected with the 2-1 to 2-4 bit lines BL21-BL24 on the 2-1 to 2-4 bit lines BL21-BL24. Each of the 3-1 to 3-4 word lines WL31-WL34 may be formed to have a fifth thickness TH5 different from the first to fourth thicknesses TH1-TH4.

The plurality of fourth memory cells MC4 may be positioned at intersections between the 2-1 to 2-4 bit lines BL21-BL24 and the 3-1 to 3-4 word lines WL31-WL34, respectively. Accordingly, the fourth deck DK4 may include 16 fourth memory cells MC4.

A fourth insulation layer may be interposed between the plurality of fourth memory cells MC4. In addition to insulating between the fourth memory cells MC4, the fourth insulation layer may also insulate between the 2-1 to 2-4 bit lines BL21-BL24 and the 3-1 to 3-4 word lines WL31-WL34.

In example embodiments, the first to fourth memory cells MC1-MC4 of the first to fourth decks DK1-DK4 may include, for example, a variable resistor Rv alone, or may include a stacked structure of a switching element SW and a variable resistor Rv.

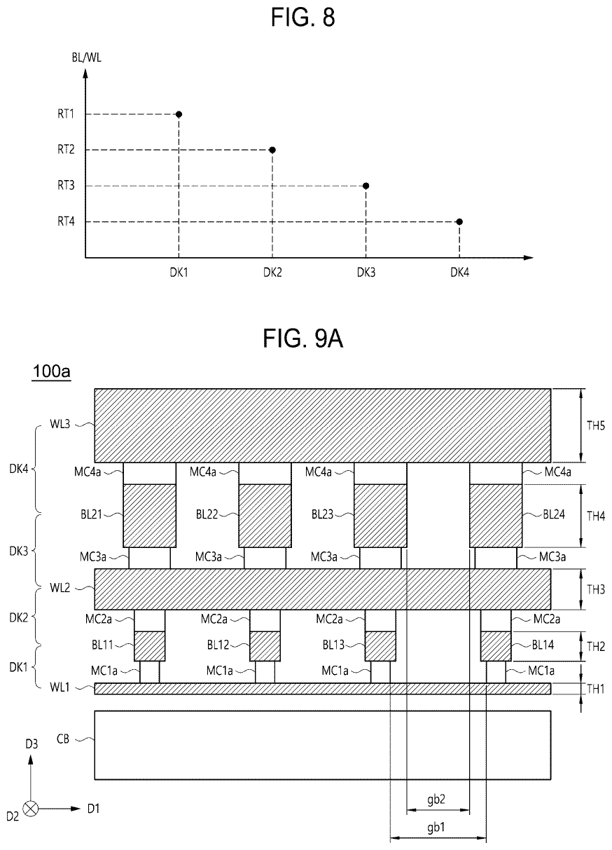

FIG. 7 is a graph showing variations of word line capacitance as a function of bit line thickness ratio to word line thickness of a variable resistance memory device in accordance with example embodiments. FIG. 8 is a graph showing a ratio of a bit line thickness to a word line thickness per memory deck in accordance with example embodiments.

As shown in a graph of FIG. 7, the word line capacitance CWL of the memory cell, which is closely related to the spike current, may be changed in accordance with a ratio of a thickness of the bit line to a thickness of the word line (BL/WL, hereinafter, a thickness ratio) associated with the memory cell.

For example, in instances in which the thickness of the word line associated with the memory cell is reduced relative to the thickness of the bit line associated with the memory cell, the thickness ratio (BL/WL) may be increased and the word line capacitance (CWL) may be reduced.

On the other hand, the word line resistance RWL, which is closely related to the spike current, may be increased proportionally to a distance between the control circuit block CB and the word lines.

Accordingly, for the first deck DK1 having the smallest word line resistance RWL, the thicknesses of the word lines and the bit lines may be set such that the memory cells of the first deck DK1 may have the lowest word line capacitance among the set word line capacitances, to reduce the effect of spike currents.

On the other hand, the word lines and the bit lines of the fourth deck DK4 farthest spaced apart from the control circuit block CB may have relatively higher word line resistance R_{WL} and bit line resistance R_{BL} than the word lines and bit lines of the other decks. Therefore, the word lines and the bit lines of the fourth deck DK4 may be formed relatively thick to compensate for the word line resistance R_{WL} and the bit line resistance R_{BL} in a range that satisfies the set word line capacitance.

This may reduce the spike current of the near memory cells while simultaneously improving the signal delay characteristics of the far memory cells.

In example embodiments, the set word line capacitance may have a range such that the memory cell may not malfunction due to spike current and/or leakage current. In this case, the set word line capacitance may be a value arbitrarily set by a designer based on the word line voltage V_{WL}, the bit line voltage V_{BL}, the word line material, the bit line material, the position of the word line, the position of the bit line, and memory cell test results.

In example embodiments, assuming that the set word line capacitance may be 1.1 E⁻¹³ C to 1.0 E⁻¹³ C, the bit line thickness ratio BL/WL for each word line thickness including each of the first to fourth decks DK1-DK4 may satisfy 2 to 20, more specifically 2.75 to 19.78.

For example, a ratio of the second thickness TH2 of the 1-1 to 1-4 bit lines BL11-BL14 to the first thickness TH1 of the 1-1 to 1-4 word lines WL11-WL14 may be adjusted in a first ratio RT1 such that the word line capacitance of the first deck DK1 closest to the control circuit block CB may have the lowest value of a set word line capacitance range.

In order to satisfy the first ratio RT1, the first thickness TH1 of the 1-1 to 1-4 word lines WL11-WL14 is provided at a thickness less than the second thickness TH2 of the 1-1 to 1-4 bit lines BL11-BL14.

The 2-1 to 2-4 word lines WL21-WL24 of the second deck DK2 may be spaced further apart from the control circuit block CB than the 1-1 to 1-4 word lines WL11-WL14 of the first deck DK1. Therefore, the third thickness TH3 of the 2-1 to 2-4 word lines WL21-WL24 may be formed thicker than the first thickness TH1 of the 1-1 to 1-4 word lines WL11-WL14, thinner than the second thickness TH2 of the 1-1 to 1-4 bit lines BL11-BL14 to the set word line capacitance. Accordingly, the ratio of the thickness of the bit lines to the thickness of the word lines of the second deck DK2 may have a second ratio RT2 less than the first ratio RT1. Accordingly, the spike currents may be prevented while compensating for a signal delay of the second deck DK2.

The 2-1 to 2-4 bit lines BL21-BL24 of the third deck DK3 may be further spaced apart from the control circuit block CB than the 1-1 to 1-4 bit lines BL11-BL14 of the first deck DK1 and the second deck DK2. Therefore, in order to compensate for the bit line signal delay of the third deck DK3 and to satisfy the set word line capacitance, the fourth thickness TH4 of the 2-1 to 2-4 bit lines BL21-BL24 may be formed thicker than the second thickness TH2 of the 1-1 to 1-4 bit lines BL11-BL14. Accordingly, the ratio BL/WL of the thickness of the bit lines to the thickness of the word lines of the third deck DK3 may have a third ratio RT3 less than the second ratio RT2. Accordingly, it may be possible to compensate for the signal delay of the third deck DK3 while preventing the generation of spike current.

The 3-1 to 3-4 word lines WL31-WL34 of the fourth deck DK4 may be spaced further apart from the control circuit block CB than the 1-1 to 1-4 word lines WL11-WL14 and the 2-1 to 2-4 word lines WL21-WL24. Therefore, the fifth thickness TH5 of the 3-1 to 3-4 word lines WL31-WL34 may be formed thicker than the third thickness TH3 of the 2-1 to 2-4 word lines WL21-WL24, but thinner than the fourth thickness TH4 of the 2-1 to 2-4 bit lines BL21-BL24 to maintain the set word line capacitance. Accordingly, the ratio BL/WL of the thickness of the bit lines to the thickness of the word lines of the fourth deck DK4 may have a fourth ratio RT4 less than the third ratio RT3. The generation of the spike current may be reduced while preventing the signal delay of the fourth deck DK4.

According to example embodiments, for each deck, the thickness of the word lines of each deck may be set to be smaller than the thickness of the bit lines to maintain the set word line capacitance. Additionally, the word line thickness and the bit line thickness may be gradually increased in proportion to the separation distance from the control circuit block. Thus, the signal delay caused by the increase in line length may be compensated while reducing the occurrence of the sudden spike current at the turn-on of the memory cell.

While example embodiments illustrate an example of four decks containing four word lines and four bit lines stacked sequentially, it will be appreciated that variations can be made with varying numbers of word lines, bit lines, and decks without limitation.

Furthermore, while example embodiments adjust the thickness of the word lines and the thickness of the bit lines to satisfy the word line capacitance range for each of the first through fourth decks DK1-DK4, it may be possible to adjust only the thickness of the word lines WL11-WL14 and the bit lines BL11-BL14 of the first deck DK1 disposed closest to the control circuit block CB.

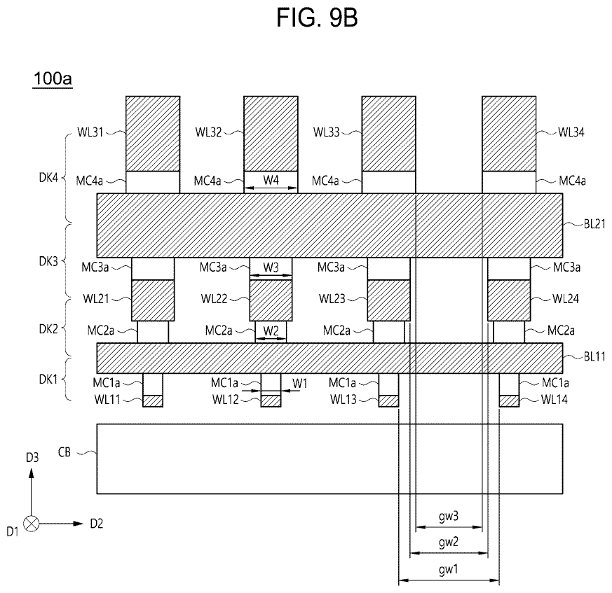

FIGS. 9A and 9B are cross-sectional views illustrating a memory cell array including a plurality of stacked decks in accordance with example embodiments. For reference, FIG. 9A is a cross-sectional view taken along a direction parallel to word lines, and FIG. 9B is a cross-sectional view taken along (for example, in) a direction parallel to bit lines. The configuration of the variable resistance memory device shown in FIGS. 9A and 9B may be substantially the same as the configuration of the variable resistance memory device shown in FIGS. 6A and 6B, with only widths of the stacked memory cells, stacked word lines, and stacked bit lines differing. Therefore, for convenience, redundant description of the same parts of the configuration of the resistance change memory device of FIGS. 6A and 6B will be omitted.

Referring to FIGS. 9A and 9B, a plurality of first memory cells MC1a of a first deck DK1 may be formed to have a first width W1. In example embodiments, in order to form the plurality of first memory cells MC1a having the first width W1, at least one of the widths of the 1-1 to 1-4 word lines WL11-WL14 and the widths of the 1-1 to 1-4 bit lines BL11-BL14 may be adjusted. For example, the 1-1 to 1-4 word lines WL11-WL14 may be formed to have the first width W1.

A plurality of second memory cells MC2a of a second deck DK2 may be formed to have a second width W2 larger than the first width W1. In example embodiments, to form the plurality of second memory cells MC2a having the second width W2, at least one of the widths of the 1-1 to first-4 bit lines BL11-BL14 and the widths of the 2-1 to 2-4 word lines WL21-WL24 may be adjusted. For example, the 1-1 to 1-4 bit lines BL11-BL14 may be formed to have the second width W2.

A plurality of third memory cells MC3a of a third deck DK3 may be formed to have a third width W3 larger than the second width W2. In example embodiments, in order to form the plurality of third memory cells MC3a having the third width W3, at least one of the widths of the 2-1 to 2-4 word lines WL21-WL24 and the widths of the 2-1 to 2-4 bit lines BL21-BL24 may be adjusted. For example, the 2-1 to 2-4 word lines WL21-WL24 may be formed to have the second width W2.

A plurality of fourth memory cells MC4a of the fourth deck DK4 may be formed to have a fourth width W4 larger than the third width W3. In example embodiments, in order to form the plurality of fourth memory cells MC4a having the fourth width W4, at least one of the widths of the 2-1 to 2-4 bit lines BL21-BL24 and the widths of the 3-1 to 3-4 word lines WL31-WL34 may be adjusted. For example, the 2-1 to 2-4 bit lines BL21-BL24 may be formed to have the fourth width W4.

According to example embodiments, the memory cells MC1a-MC4a of the stacked variable resistance memory device may be configured such that the width of the memory cells MC1a-MC4a may decrease with increasing proximity to the control circuit block CB. The change in the width of the memory cells MC1a-MC4a may be accompanied by the change in the width of the word lines WL11-WL34 or the bit lines BL11-BL24 including the memory cells MC1a-MC4a.

Accordingly, a gap gw1 between the control circuit block CB and the word lines WL11-WL14 of the adjacent deck (e.g., the first deck) and a gap gb1 between the bit lines BL11-BL14 may be increased more than a gap gw2 between the word lines WL21-WL24 and the bit lines BL21-BL24 of the deck (e.g., the second memory deck) spaced apart from the control circuit block CB.

As a result, the gap gw1 between the word lines WL11-WL14 of the first deck adjacent to the control circuit block CB and the gap gb1 between the bit lines BL11-BL14 may be increased relative to the word line gaps gw2 and gw3 and the bit line gap gb2 of the other decks DK2-DK4, so that the word line capacitor and the bit line capacitor of the first deck DK1 may be relatively reduced. Accordingly, the size of the parasitic capacitor in which the residual charge may be stored may be reduced, thereby preventing the generation of a spike current.

Furthermore, the widths of the word lines WL11-WL14 of the first deck DK1 adjacent to the control circuit block CB and the widths of the bit lines BL11-BL14 may be reduced relative to the widths of the word lines WL21-WL34 or the bit lines BL21-BL24 of the other decks DK2-DK4. The resistance of the word lines WL11-WL14 and the resistance of the bit lines BL11-BL14 of the first deck DK1 may be increased.

Compared to the other decks DK2-DK4, the parasitic capacitance of the word lines WL11-WL14 and the bit lines BL11-BL14 of the first deck DK1 adjacent to the control circuit block CB may be reduced, and the resistance of the word lines WL11-WL14 and the bit lines BL11-BL14 may be increased, so that when the memory cell MC1a of the first deck DK1 is selected, the effect of sudden spike currents may be reduced.

According to example embodiments, in the stacked memory device, the bit line thickness to the word line thickness, and the width of the memory cell may be selected (for example, determined and/or provided) in accordance with the separation distance from the control circuit block to prevent the malfunction due to sudden spike currents during the memory cell selection.

Furthermore, the present disclosure is not limited to the example embodiments shown herein. For example, in instances in which the turn-on of the memory cell is determined by the bit line voltage having the negative voltage level, the spike current due to parasitic bit-line capacitance may also be reduced by the same principle as described above.

While the present invention has been described in detail with reference to preferred embodiments, the invention is not limited to the above embodiments, but is capable of many modifications by those having ordinary skill in the art within the scope of the technical ideas of the invention.

What is claimed is:

1. A variable resistance memory device comprising:
a control circuit block configured to output a plurality of control voltages;
a first deck arranged over the control circuit block, the first deck including
a plurality of first word lines,
a plurality of first bit lines intersected with the plurality of first word lines, and
a plurality of first memory cells positioned at intersections between the plurality of first word lines and the plurality of first bit lines, respectively; and
a second deck arranged over the first deck, the second deck including
the plurality of first bit lines,
a plurality of second word lines intersected with the plurality of first bit lines, and
a plurality of second memory cells positioned at intersections between the plurality of first bit lines and the plurality of second word lines,
wherein first deck is spaced apart from the control circuit block by a first distance, and the second deck is spaced apart from the control circuit block by a second distance greater than the first distance,
wherein a ratio of a thickness of the first bit line to a thickness of the first word line is a first ratio, and a ratio of the thickness of the first bit line to a thickness of the second word line is a second ratio less than the first ratio, and
wherein the first word lines, the first bit lines, the second word lines and the second bit lines of the first and second decks receives the control voltages.

2. The variable resistance memory device of claim 1, wherein each of the plurality of first word lines has a first thickness, each of the plurality of first bit lines has a second thickness greater than the first thickness, and each of the plurality of second word lines has a third thickness greater than the first thickness and less than the second thickness.

3. The variable resistance memory device of claim 1, wherein
the first ratio and the second ratio are in a range of 2 and 20.

4. The variable resistance memory device of claim 1, wherein a width of each of the first memory cell is less than a width of each of the second memory cell.

5. The variable resistance memory device of claim 4, wherein a width of the first word line is less than a width of the second word line.

6. The variable resistance memory device of claim 1, wherein a gap between adjacent two first word lines is greater than a gap between adjacent two second word lines.

7. The variable resistance memory device of claim 1, further comprising:
a third deck arranged over the second deck,
wherein the third deck includes the plurality of second word lines, a plurality of second bit lines intersected with each other, and a plurality of third memory cells positioned at intersections between the plurality of second word lines and the plurality of second bit lines, respectively, and
wherein the third deck is spaced apart from the control circuit block by a third distance greater than the second distance.

8. The variable resistance memory device of claim 7, wherein a ratio of a thickness of the second word line to a thickness of the second bit line is a third ratio less than the second ratio.

9. The variable resistance memory device of claim 8, wherein the first ratio, the second ratio, and the third ratio are in a range of 2 to 20.

10. The variable resistance memory device of claim 7, wherein each of the first word lines has a first thickness, each of the plurality of first bit lines has a second thickness greater than the first thickness, each of the plurality of second word lines has a third thickness greater than the first thickness and less than the second thickness, and each of the plurality of second bit lines have a fourth thickness greater than the second thickness.

11. The variable resistance memory device of claim 7, wherein a width of each of the first memory cells is less than a width of each of the second memory cells, and a width of each of the second memory cells is narrower than a width of each of the third memory cells.

12. A variable resistance memory device comprising:
a control circuit block;
a first deck stacked over the control circuit block, the first deck including a plurality of first memory cells connected between a plurality of first word lines and a plurality of first bit lines, and each of the plurality of first memory cells having a first width;
a second deck stacked over the first deck, the second deck including a plurality of second memory cells connected between the plurality of first bit lines and the plurality of second word lines, and each of the plurality of second memory cells having a second width greater than the first width;
a third deck stacked over the second deck, the third deck including a plurality of third memory cells connected between the plurality of second word lines and the plurality of second bit lines, and each of the plurality of the third memory cells including a third width greater than the second width; and
a fourth deck stacked over the third deck, the fourth deck including a plurality of fourth memory cells connected between the plurality of second bit lines and the plurality of third word lines, and each of the plurality of fourth memory cells having a fourth width greater than the third width.

13. The variable resistance memory device of claim 12, wherein a ratio of a thickness of the first bit line to a thickness of the first word line is a first ratio, and a ratio of the thickness of the first bit line to a thickness of the second word line is a second ratio less than the first ratio.

14. The variable resistance memory device of claim 12, wherein a ratio of a thickness of the first bit line to a thickness of the first word line is a first ratio, a ratio of the thickness of the first bit line to a thickness of the second word line is a second ratio less than the first ratio, a ratio of a thickness of the second bit line to the thickness of the second word line is a third ratio less than the second ratio, and a ratio of a thickness of the second bit line to the thickness of the third word line is a fourth ratio less than the third ratio.

15. The variable resistance memory device of claim 12, wherein each of the plurality of first word lines has the first width, each of the plurality of first bit lines has the second width, each of the plurality of second word lines has the third width, and each of the plurality of second bit lines have the fourth width.

16. The variable resistance memory device of claim 15, wherein each of the plurality of first word lines has a first thickness, each of the plurality of first bit lines has a second thickness greater than the first thickness, each of the plurality of second word lines has a third thickness greater than the first thickness and less than the second thickness, each of the plurality of second bit lines has a fourth thickness greater than the second thickness, and each of the plurality of third word lines has a fifth thickness greater than the third thickness and less than the fourth thickness.

17. A variable resistance memory device comprising:
a control circuit block;
a plurality of word lines and a plurality of bit lines alternately intersected with each other and stacked over the control circuit block; and
a plurality of variable resistors connected to intersections between the plurality of word lines and the plurality of bit lines,
wherein a capacitance of each of the plurality of word lines and the plurality of bit lines is adjusted based on proximity to the control circuit block to reduce an effect of spike currents.

18. The variable resistance memory device of claim 17, wherein the plurality of bit lines have at least one of a thickness and a width reduced as the plurality of bit lines are adjacent to the control circuit block.

19. The variable resistance memory device of claim 17, wherein a thickness of the bit line connected to one end of the variable resistor is thinner than a thickness of the bit line connected to the other end of the variable resistor.

20. The variable resistance memory device of claim 17, wherein at least one of a thickness and a width of the plurality of word lines is reduced as a distance from the control circuit block is increased.
